(19) United States
(12) Patent Application Publication
(10) Pub. No.: US 2008/0178927 A1
(43) Pub. Date: Jul. 31, 2008

(54) Photovoltaic apparatus having an elongated photovoltaic device using an involute-based concentrator

(76) Inventors: Thomas Brezoczky, Los Gatos, CA (US); Chris M. Gronet, Portola Valley, CA (US); Benyamin Buller, Cupertino, CA (US)

Correspondence Address: JONES DAY, 222 EAST 41ST ST, NEW YORK, NY, 10017, US

(21) Appl. No.: 11/810,283

(22) Filed: Jun. 5, 2007

Related U.S. Application Data
(60) Provisional application No. 60/898,454, filed on Jan. 30, 2007.

(51) Int. Cl. H01L 31/058; H01L 31/052

(52) U.S. Cl. 136/248

(57) ABSTRACT

An apparatus for converting light energy into electric energy has a concentrator with at least a first and second wall. The walls are made at least in part of a material that reflects light. The concentrator has an opening defined by the walls, and is operable to admit light energy into an interior portion of the apparatus. An elongated photovoltaic module is disposed between the walls. The module has a substrate, and a photovoltaic covering disposed on the substrate. The module can generate electric energy from light energy that directly strikes the module and light energy redirected from the concentrator to the module. The walls are substantially the shape of an involute of the module. The walls are limited to the height of the topmost portion of the elongated photovoltaic module. The module is disposed upon or above a joining of the walls.

### CROSS-REFERENCE TO RELATED APPLICATION

This application claims benefit under 35 U.S.C. § 119(e), of U.S. Provisional Patent Application No. 60/898,454, filed on Jan. 30, 2007, which is hereby incorporated by reference herein in its entirety.

### BACKGROUND

This application is directed to photovoltaic solar cell apparatus construction. In particular, it is directed to a photovoltaic cell or module and an associated reflector.

FIG. 1 is a schematic block diagram of a conventional photovoltaic (PV) device. A photovoltaic module 10 can typically have one or more photovoltaic cells 12a-b disposed within it. A photovoltaic cell conventionally is made by having a semiconductor junction 14 disposed between a layer of conducting material 18 and a layer of transparent conducting material 16. Light impinges upon the photovoltaic module 10 and transits through the transparent conducting material layer 16. Within the semiconductor, the photons interact with the material to produce electron-hole pairs within the semiconductor junction layer 14. The semiconductor(s) typically is/are doped creating an electric field extending from the junction layer 14. Accordingly, when the holes and/or electrons created by the sunlight in the semiconductor, they will migrate depending on the polarity of the device either to the transparent conducting material layer 16 or the conducting material layer 18. This migration creates current within the cell which is routed out of the cell for storage and/or concurrent use.

One conducting node of the solar cell 12a is shown electrically coupled to an opposite node of another solar cell 12b. In this manner, the current created in one cell may be transmitted to another, where it is eventually collected. The currently depicted apparatus in FIG. 1 is shown where the solar cells are coupled in series, thus creating a higher voltage device. In another manner, (not shown) the solar cells can be coupled in parallel which increases the resulting current rather than the voltage.

FIG. 2 is a schematic block diagram of a photovoltaic apparatus. The photovoltaic apparatus has a photovoltaic panel 20, which contains the active photovoltaic devices, such as those described supra. The photovoltaic panel 20 can be made up of one or multiple photovoltaic cells, photovoltaic modules, or other like photovoltaic devices, singly or multiples, solo or in combination with one another. A frame 22 surrounds the outer edge of the photovoltaic panel that houses the active photovoltaic devices. The frame 22 can be disposed flat or at an angle relative to the plane of photovoltaic panel 20.

FIG. 3 is a side cross sectional view of the photovoltaic apparatus shown in FIG. 2. In this case, the cross section is taken along the line A-A shown above in FIG. 2. The photovoltaic panel has a photovoltaic solar device 18 disposed within the frame 22. A glass, plastic, or other translucent barrier 26 is held by the frame 22 to shield the photovoltaic device 18 from an external environment. In some conventional photovoltaic apparatuses, another laminate layer 24 is placed between the photovoltaic device 18 and the translucent barrier 26.

Light impinges through the transparent barrier 26 and strikes the photovoltaic device 18. When the light strikes and is absorbed in the photovoltaic device 18, electricity can be generated much like as described with respect to FIG. 1.

In terms of planar topologies, these geometries are not highly effective in capturing diffuse and/or reflected light, due to their unifacial makeup (i.e. their ability to capture light emanating from one general direction). Accordingly, cells or modules that are bifacial (able to capture and convert light from both an “upwards” orientation and a “downwards” orientation) are more effective at utilizing such diffuse or reflected light. In the case of a cylindrical cell or module, these can capture and utilize light from any direction. Accordingly they are labeled as omnifacial devices, and such omnifacial devices are not necessarily strictly limited to those cells or modules having circular cross sections.

In most conventional planar topologies, the effective area of the active collection area is substantially equivalent to the entire effective area of the panel. This is since the planar topology dictates that the active devices must utilize as much area as possible in their deployment.

In some photovoltaic (PV) applications, elongated PV devices or modules can be arranged in a lattice-like arrangement to collect light radiation and transform that collected radiation into electric energy. In these applications, a generic reflector or albedo surface can be used as a backdrop in conjunction with an elongated solar cell or module, where the reflected, diffuse, or secondary light (e.g. the non-direct path light relative to the source) can be collected, especially when used in conjunction with solar cells or modules that have more than one collection surface (e.g. non-unifacial), or when used with solar cells or modules that are omnifacial in nature (e.g. having a non-planar geometry). However, the geometries of the collection devices are not typically closely tied to the geometries of the reflection devices, resulting in efficiency losses for the associated collection and conversion devices.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a schematic block diagram of a conventional photovoltaic device.

FIG. 2 is a schematic block diagram of a conventional photovoltaic apparatus.

FIG. 3 is a side cross-sectional view of the photovoltaic apparatus shown in FIG. 2.

FIG. 4 is a perspective view of a photovoltaic collection system.

FIG. 5 is a cut-away view of the collection system of FIG. 4, detailing the light capture properties of the collection system.

FIG. 6 is a cut-away view detailing the development of the involute of the side of the elongated photovoltaic module.

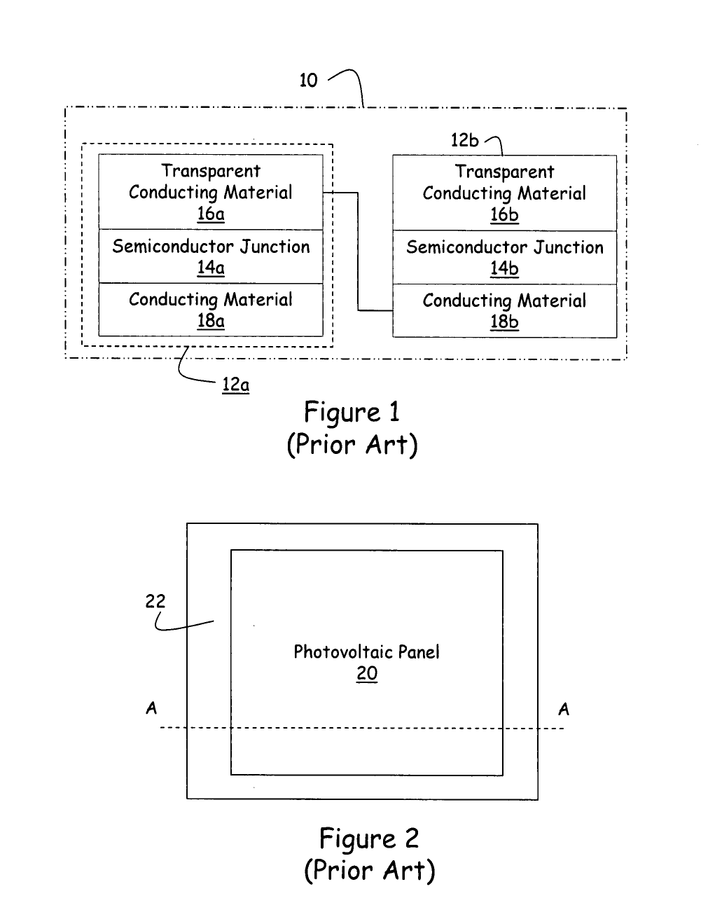

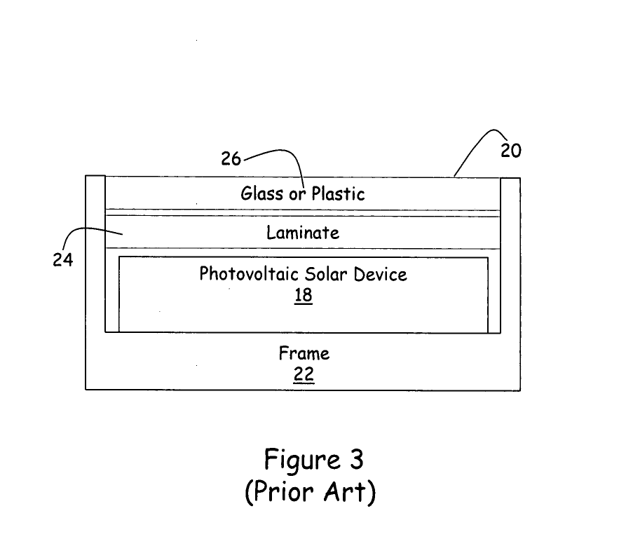

### DETAILED DESCRIPTION

Embodiments of the present invention are described herein in the context of a solar cell architecture having a laminate layer. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

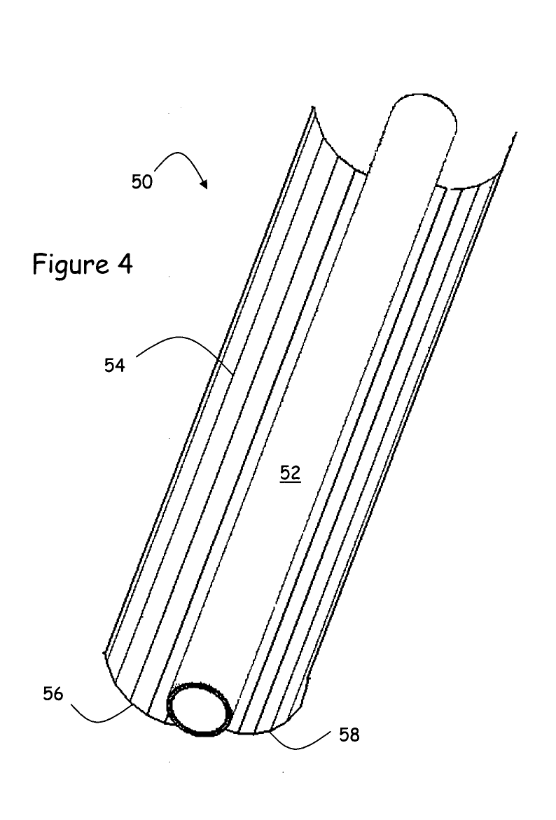

FIG. 4 is a perspective view of a photovoltaic collection system 50. A photovoltaic collection system 50 has an elongated photovoltaic solar cell or module 52. For the purposes of this disclosure, an elongated module may be described as an integral formation of a plurality of photovoltaic solar cells, coupled together electrically in an elongated structure. Examples of such elongated modules that include an integral formation of a plurality of photovoltaic cells is found in U.S. patent application Ser. Nos. 11/378,835, filed Mar. 18, 2006, and 11/799,940, filed, Mar. 18, 2006, each of which is hereby incorporated by reference in its entirety. For instance, each photovoltaic cell may occupy a portion of an underlying substrate and the cells may be monolithically integrated with each other so that they are electrically coupled to each other either in series or parallel. Alternatively, the elongated photovoltaic module 52 may be one single solar cell that is disposed on a substrate. For brevity sake, the current discussion will address the entire photovoltaic structure 52 as a module, and it should be understood that this contemplates either a singular elongated solar cell or a series of solar cells disposed along the elongated structure.

The photovoltaic collection system also has a concentrator 54 associated with it. The concentrator 54 generally forms a concave surface, in which the elongated photovoltaic module 52 is placed. The concentrator 54 is typically made of non-absorbing or low-absorbing material with respect to light energy. In one embodiment, the concentrator 54 can be made with a specular or reflective material, such that a high proportion of light energy striking it is reflected (as opposed to absorbed).

The concentrator 54 is made of a first wall 56 and a second wall 58. Each wall bounds an opposite side of the included elongated photovoltaic module 52. In the embodiment depicted, the wall 56 ends at a point tangent or substantially tangent to the elongated photovoltaic module 52. In a similar manner, the wall 58 ends at a point tangent or substantially tangent to the topmost portion of the elongated photovoltaic module 52.

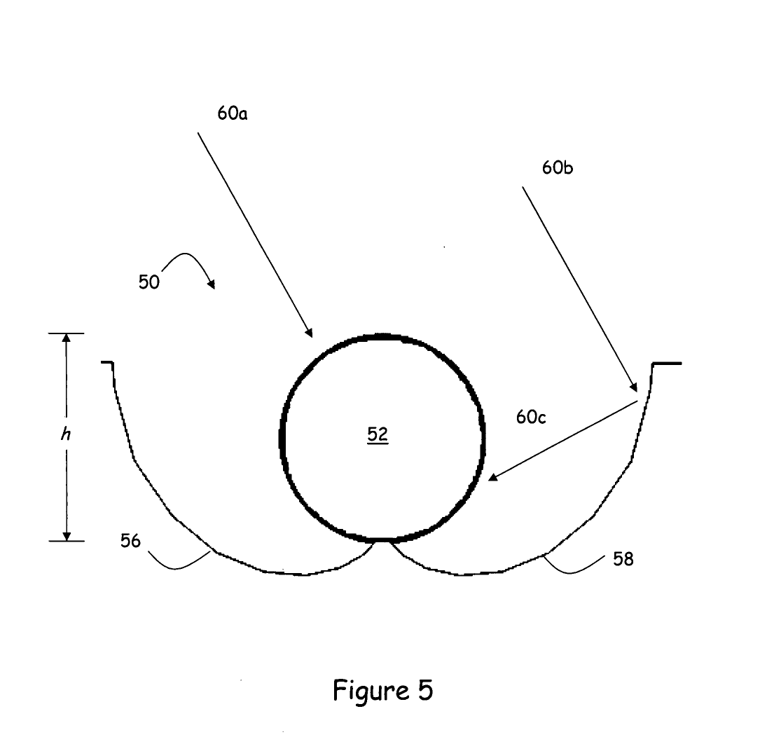

FIG. 5 is a cut-away view of the collection system 50 of FIG. 4, detailing the light capture properties of the collection system 50. In the photovoltaic collection system 50, the light from a source approaches the opening defined by the wall 56 and the wall 58, and enters into an interior defined by the wall 56 and the wall 58. A light ray 60a enters the photovoltaic collection system 50 and directly strikes the elongated photovoltaic module 52, where it is absorbed and converted to electric energy. Another light ray 60b enters the photovoltaic collection system 50 and strikes the wall 58. The wall 58 redirects the light ray 60b thereby forming light ray 60c. The redirected light ray 60c is redirected from its original path 60b to one that strikes the photovoltaic module 52, albeit from a direction other than the plane directly facing the opening defined by the wall 56 and the wall 58.

Thus, the system as depicted can produce electric energy from light that directly strikes the elongated photovoltaic module 52 from the initial source. Further, the system as depicted can produce electric energy from light that is not necessarily directed at the forward face of the elongated photovoltaic module 52. This is advantageous, because, as noted in the background section, conventional photovoltaic collection designs are limited to the use of light directed at the forward face of the solar panel. Further, the aspect of the elongated photovoltaic module 52 corresponding to multiple light energy collection and/or conversion areas allows redirected light to be collected and transformed on the side facing of the module, the back facing of the module, or both. In this manner, diffuse light collection and transformation can be substantially improved.

The shape of the wall 56 and the wall 58 are defined as involutes or substantially the involutes of the sides of the elongated photovoltaic module 52. An involute is a shape that is dependent upon the shape of another object, where that object is made up of substantially smooth curves, or from a series of faces that approximate a smooth curve. It will be appreciated that walls 56 and 58 may be separated pieces as depicted in FIGS. 4 and 5. In alternative embodiments, walls 56 and 58 may be molded as a single piece. In such embodiments, the single piece includes involute sections 56 and 58 with a connector section that joins the two sections together thereby forming a single piece.

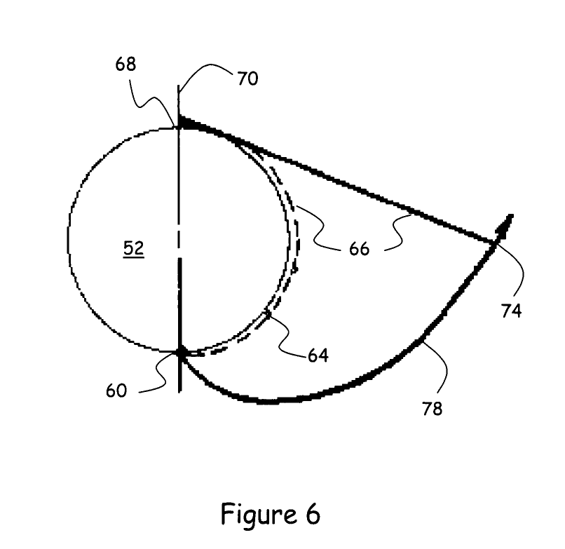

FIG. 6 is a cut-away view detailing the development of the involute of the side of the elongated photovoltaic module. In FIG. 6, the elongated photovoltaic module 52 is shown having the same circular cross-section as the elongated photovoltaic module depicted in FIG. 4 and in FIG. 5. The involute of side 64 of the elongated photovoltaic module 52 is formed as follows. A fixed point 68 of the elongated photovoltaic module 52 is defined to be the topmost point of the circular cross-section of the elongated photovoltaic module. A fixed point 68 lies on a reference axis 70, and the reference axis 70 includes a point 60 on the elongated photovoltaic module. The point 60 corresponds to the point that the elongated photovoltaic module rests on the juncture of the wall 56 and the wall 58. A thread 66 is fastened to elongated photovoltaic module 52 at the fixed point 68, and the length of the thread 66 is defined as half of the circumference of the circular cross section of the elongated photovoltaic module 52.

Assume that the thread 66 is wrapped around the elongated photovoltaic module 52 in a clockwise direction and held taut. The locus of the end 74 of the thread 66 as it is wrapped (or unwrapped) from the elongated photovoltaic module 52 defines curve 78 of FIG. 5, and is the involute of the side 64 of elongated photovoltaic module 52, where side 64 is the portion of module 52 that corresponds to curve 78 and hence is the evolute of curve 78. Curve 78 of FIG. 5 corresponds to substantially the shape of the wall 58 of FIGS. 4 and 5.

Correspondingly, the shape of the wall 56 is determined in a substantially similar manner, but with the direction of the wrapping of thread 66 being oriented in a counter-clockwise orientation. In some embodiments, as depicted in FIGS. 4-5, walls 56 and 58 tangentially touch module 52 on the side of module 52 that faces away from direct light. However, it will be appreciated that there is no requirement for walls 56 and 58 to contact module 52 in order to form the involute of the sides of module 52. Although a curve has a unique evolute, it has infinitely many involutes corresponding to different choices of initial and final points. Thus, consider the case where the initial point of involute curve 78 is as discussed for FIG. 6, point 68, but the final point of curve 78 is reached at some point before curve 78 touches module 52 at point 60. Such a curve is still the involute of module 52 and within the scope of the present invention. In some embodiments, walls 56 and 58 are limited by the height h of module 52 but are not involute as they approach the bottom of module 52 in the vicinity of point 60 of FIG. 6. In some instances, a joinder piece that in not the involute of any surface of module 52 joins walls 56 and 58 together and supports module 52 in the vicinity of point 60. In some embodiments, this joinder (not shown), and the involute portions of walls 56 and 58 are a single integrated piece. In some embodiments, the joinder includes a groove that is complementary to the shape of the bottom portion of module 52. For example, in some embodiments, module 52 is cylindrical and the joinder includes a groove into which a bottom portion of module 52 fits.

The results from the involute topology described in conjunction with FIGS. 4-6 is that a substantial proportion of the light entering the area delineated between the wall 56 and the wall 58 is eventually directed onto the elongated photovoltaic module 52. Thus the effective area of the elongated photovoltaic module 52 is dramatically increased.

In terms of the geometry, the involute is especially efficient in transmitting reflected light. In particular, when one uses the involute of the base shape of the elongated photovoltaic module with the elongated photovoltaic module, this will cause a light ray impinging on any portion of the involute reflector to eventually be transmitted to the elongated photovoltaic module. Thus, there is an extraordinarily high proportion of the light impinging into the area defined between the wall 56 and the wall 58 that reaches that elongated photovoltaic module 52 when using the involute shape reflector.

In this particular case (e.g. the cross section of the elongated photovoltaic module being a circle), the surface of the concentrator 54 can be. categorized as having substantially the shape defined in the x and y coordinate system depicted on FIG. 5. The equation describing the reflecting surface in the coordinate system can be described in equations (1) and (2), below:

x=a(cos(α)+α sin(α)); (1)

y=a(cos(α)−α sin(α)); (2)

where α is a particular angle rotation about module 52, and a is the radius of module 52. This applies to each wall as specified with the proper turning direction.

In constructing a reflector for use in a practical application, the involute need not extend vertically a substantial distance. In fact, the involute is best limited to having a side wall only as high as the topmost portion of the elongated photovoltaic module 52, using the orientations of FIG. 5 for reference, or having a rotation angle of the involute extending ½ of the diameter around the circular cross-section as noted.

This orientation provides two advantages. First, shadowing of the elongated photovoltaic module 52 would be increased if the vertical wall extended more than the topmost level of the elongated photovoltaic module 52. This is since the involute, if extended to this angle, would actually begin to bend inward over the elongated photovoltaic module 52. Second, this limitation limits the amounts of material used in the construction of the wall 56 and the wall 58. This saves time, money, and fabrication expenses to make the particular concentrator 54.

In some cases, the height at which the reflector surface ends corresponds to the topmost portion of the elongated photovotaic module using the orientations of FIG. 5 for reference. In another case, the height at which the concentrator 54 surface ends corresponds to a point that exceeds the height of the topmost portion of the photovoltaic module by up to 10% of the total height h of module 52 using FIG. 5 for reference. In some embodiments the side of the concentrator 54 ends at a height corresponding the to the midpoint diameter of module 52 in embodiments where module 52 is cylindrical or approximately cylindrical. Other potential ending heights for the side of the concentrator 54 can also be d/2, d/4, 3d/4, 3d/8, 5d/8, 7d/8, 5/16d, 7/16d, 9d/16, 11d/16, 13d/16, and 15d/16, where d is the height h of the elongated photovoltaic module as illustrated in FIG. 5. Any height between d/2 and d can be thought of as providing very good energy conversion ratios. One should note that the height h of the concentrator 54 can be any height. Moreover, in some embodiments, only a portion of wall 56 and/or wall 58 forms the involute of a corresponding evolute of module 52. For example, if wall 56 and/or wall 58 is considered in terms of the curve swept out by the respective wall as illustrated, for example by curve 78 of FIG. 6, in some embodiments, fifty percent or more of the curve swept out by wall 56 and/or wall 58 is an involute of a corresponding evolute of module 52. In some embodiments, sixty percent or more, seventy percent or more, eighty percent or more, ninety percent or more, or all of the curve swept out by wall 56 and/or wall 58 is an involute of a corresponding evolute of module 52. The balance of the curve swept out by wall 56 and/or 58 in such embodiments can adopt any shape that will facilitate the function of concentrator 54, either in its role as a concentrator, or in an auxiliary role as a physical support for module 52 or physically integrate module 52 into a planar array of modules.

In one embodiment, a series of photovoltaic modules 52 are envisioned, each with a corresponding involute-based concentrator 54. Each structure is arranged in parallel. Accordingly, light that would otherwise be channeled to the photovoltaic module 52 by an extended side of the reflector is instead captured by a neighboring concentrator/photovoltaic module structure.

It should be noted that the photovoltaic module depicted need not be cylindrical in nature. In fact, the photovoltaic module needs only have bifacial or omnifacial characteristics to enjoy the benefits of the involute concentrator. Correspondingly, the concentrator should be constructed as the involute of whatever shape the photovoltaic module would be. Accordingly, any cross-sectional geometry of elongated photovoltaic module is envisioned, and any involute of such a cross section is envisioned to coordinate with the particular cross-section.

In some embodiments, the wall 56 and the wall 58 may not be wholly an involute shape. In these cases, the walls can deviate from the involute shape in order to achieve some other engineering function. For example, a mechanical joint can be added to the end of the wall 56, such that the mechanical joint is able to latch or otherwise attach to some retaining device, such as a frame. Thus, the full proportion of the wall 56 need not wholly conform to the involute shape.

When the wall 56 of the concentrator 54 stands at the level of the topmost portion of the elongated photovoltaic module 52 as illustrated in FIG. 5, and the cross section of the photovoltaic module is circular, the distance between the topmost portion of the elongated photovoltaic module 52 and the wall 56 is c/2, where c is the circumference of the included elongated photovoltaic module 52, or in other words πd/2, where d is the diameter of the circular cross section of a cylindrical photovoltaic module 52. Thus, when two constructs are placed in parallel, the distance between the midpoints of adjoining photovoltaic modules is 2*(πd)/2, or simply πd. The distance between the edges of adjoining photovoltaic modules is 2*(π−1)*d. Of course, this is when the involutes are in a strict side-to-side touching mode. One could introduce a thickness to the top edge of the wall, introducing more distance between the individual involute—module structures.

The active effective area engaged in solar collection and conversion is the area bounded by the two elongated photovoltaic modules, which is proportional to 2 d. The total area of the two collection systems is proportional to 2πd. Thus, the ratio of total effective collection area to effective active collection and conversion area is 2πd: 2 d, or simply π:1.

The composition of the concentrator 54 surface (e.g. the wall 56 and the wall 58) is a specular material in some embodiments. High specular material is desired, since this will reduce reflection loss. The wall 56 and the wall 58 can be manufactured from such materials as aluminum or aluminum alloy. In another embodiment, the material can be one that is diffuse.

In one embodiment, the concentrator 54 is made as a thin panel of the reflective material overlayed on a substrate or mold. In one embodiment, the concentrator can be made as a single sheet of material. In another embodiment, the concentrator 54 can be made of or machined from a block of reflective material.

In another embodiment, the concentrator 54 can be made of a substrate coated with specular material. For example, the concentrator 54 could be made as a substrate of a plastic, and then coated with a specular material such as aluminum. In some cases, the specular material can be polished to enhance the reflective properties. Or, the material can also be coated with a sealant to preserve the specular properties, especially when the specular material is polished.

In context, the above-described solar cell can be made of various material, and in any variety of manners. Examples of compounds that can be used to produce the semiconductor photovoltaic cell 18 can include Group IV elemental semiconductors such as: carbon (C), silicon (Si) (both amorphous and crystalline), germanium (Ge); Group IV compound semiconductors, such as: silicon carbide (SiC), silicon germanide (SiGe); Group III-V semiconductors, such as: aluminum antimonide (AlSb), aluminum, arsenide (AlAs), aluminum nitride (AlN), aluminum phosphide (AlP), boron nitride (BN), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP); Group III-V ternary semiconductor alloys, such as: aluminum gallium arsenide (AlGaAs, AlxGa₁₋ₓAs), indium gallium arsenide (InGaAs, InxGa₁₋ₓAs), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb); Group III-V quaternary semiconductor alloys, such as: aluminum gallium indium phosphide (AlGaInP, also InAlGaP, InGaAlP, AlInGaP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN); Group III-V quinary semiconductor alloys, such as: gallium indium nitride arsenide antimonide (GaInNAsSb); Group III-VI semiconductors, such as: cadmium selenide (CdSe), cadmium sulfide (CdS), cadmium telluride (CdTe), zinc oxide (ZnO), zinc selenide (ZnSe), zinc sulfide (ZnS), zinc telluride (ZnTe); Group III-VI ternary alloy semiconductors, such as: cadmium zinc telluride (CdZnTe, CZT), mercury cadmium telluride (HgCdTe), mercury zinc telluride (HgZnTe), mercury zinc selenide (HgZnSe); Group III-VII semiconductors, such as: cuprous chloride (CuCl); Group IV-VI semiconductors, such as: lead selenide (PbSe), lead sulfide (PbS), lead telluride (PbTe), tin sulfide (SnS), tin telluride (SnTe); Group IV-VI ternary semiconductors, such as: lead tin telluride (PbSnTe), thallium tin telluride (TI₂SnTe₅), thallium germanium telluride (TI₂GeTe₅); Group V-VI semiconductors, such as: bismuth telluride (Bi₂Te₃); Group II-V semiconductors, such as: cadmium phosphide (Cd₃P₂), cadmium arsenide (Cd₃As₂), cadmium antimonide (Cd₃Sb₂), zinc phosphide (Zn₃P₂), zinc arsenide (Zn₃As₂), zinc antimonide (Zn₃Sb₂); layered semiconductors, such as: lead(II) iodide (PbI₂), molybdenum disulfide (MOS₂), gallium selenide (GaSe), tin sulfide (SnS), bismuth sulfide (Bi₂S₃); others, such as: copper indium gallium selenide (CIGS), platinum silicide (PtSi), bismuth(III) iodide (BiI₃), mercury(II) iodide (HgI₂), thallium(I) bromide (TIBr); or miscellaneous oxides, such as: titanium dioxide anatase (TiO₂), copper(I) oxide (Cu₂0), copper(II) oxide (CuO), uranium dioxide (UO₂), or uranium trioxide (UO₃). This listing is not exclusive, but exemplary in nature. Further, the individual grouping lists are also exemplary and not exclusive. Accordingly, this description of the potential semiconductors that can be used in the photovoltaic should be regarded as illustrative.

The foregoing materials may be used with various dopings to form a semiconductor junction. For example, a layer of silicon can be doped with an element or substance, such that when the doping material is added, it takes away (accepts) weakly-bound outer electrons, and increases the number of free positive charge carriers (e.g. a p-type semiconductor.) Another layer can be doped with an element or substance, such that when the doping material is added, it gives (donates) weakly-bound outer electrons addition and increases the number of free electrons (e.g. an n-type semiconductor.) An intrinsic semiconductor, also called an undoped semiconductor or i-type semiconductor, can also be used. This intrinsic semiconductor is typically a pure semiconductor without any significant doping. The intrinsic semiconductor, also called an undoped semiconductor or i-type semiconductor, is a pure semiconductor without any significant dopants present. The semiconductor junction layer can be made from various combinations of p-, n-, and i-type semiconductors, and this description should be read to include those combinations.

The photovoltaic device may be made in various ways and have various thicknesses. The photovoltaic device as described herein may be a so-called thick-film semiconductor structure or a so-called thin-film semiconductor structure as well.

An apparatus for converting light energy into electric energy has a concentrator with at least a first wall and a second wall. The first wall and the second wall are made at least in part of a material that reflects light. The concentrator has an opening defined by the first wall and the second wall, and is operable to admit light energy into an interior portion of the apparatus.

An elongated photovoltaic module is disposed between the two walls. The module has a substrate, and a photovoltaic covering disposed on the substrate that converts light energy into electric energy. The module can generate electric energy from light energy that directly strikes the module light energy redirected from the concentrator to the module.

In some embodiments, the module substrate is rigid. Rigidity of a material can be measured using several different metrics including, but not limited to, Young's modulus. In solid mechanics, Young's Modulus (E) (also known as the Young Modulus, modulus of elasticity, elastic modulus or tensile modulus) is a measure of the stiffness of a given material. It is defined as the ratio, for small strains, of the rate of change of stress with strain. This can be experimentally determined from the slope of a stress-strain curve created during tensile tests conducted on a sample of the material. Young's modulus for various materials is given in the following table.

| | Young's | |
|---|---|---|
| | modulus (E) in | Young's modulus |
| Material | GPa | (E) in lbf/in² (psi) |
| Rubber (small strain) | 0.01-0.1 | 1,500-15,000 |
| Low density polyethylene | 0.2 | 30,000 |
| Polypropylene | 1.5-2 | 217,000-290,000 |
| Polyethylene terephthalate | 2-2.5 | 290,000-360,000 |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced | 150 | 21,800,000 |
| plastic (unidirectional, | | |
| along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments, the elongated photovoltaic module (e.g., the module substrate) is deemed to be rigid when it is made of a material that has a Young's modulus of 20 GPa or greater, 30 GPa or greater, 40 GPa or greater, 50 GPa or greater, 60 GPa or greater, or 70 GPa or greater. In some embodiments a material (e.g., the module substrate) is deemed to be rigid when the Young's modulus for the material is a constant over a range of strains. Such materials are called linear, and are said to obey Hooke's law. Thus, in some embodiments, the module substrate is made out of a linear material that obeys Hooke's law. Examples of linear materials include, but are not limited to, steel, carbon fiber, and glass. Rubber and soil (except at very low strains) are non-linear materials.

In some embodiments the elongated photovoltaic module can be cylindrical or rod shaped. In some embodiments, all or a portion of the elongated photovoltaic module can be characterized by a cross-section bounded by any one of a number of shapes other than the circular shaped depicted in FIG. 6. The bounding shape can be any one of circular, ovoid, or any shape characterized by one or more smooth curved surfaces, or any splice of smooth curved surfaces. The bounding shape can be an n-gon, where n is 3, 5, or greater than 5. The bounding shape can also be linear in nature, including triangular, rectangular, pentangular, hexagonal, or having any number of linear segmented surfaces. Or, the cross-section can be bounded by any combination of linear surfaces, arcuate surfaces, or curved surfaces. As described herein, for ease of discussion only, an omnifacial circular cross-section is illustrated to represent nonplanar embodiments of the elongated photovoltaic module. However, it should be noted that any cross-sectional geometry may be used in the elongated photovoltaic module that is nonplanar in practice.

In some embodiments, a first portion of the elongated photovoltaic module is characterized by a first cross-sectional shape and a second portion of the elongated photovoltaic module is characterized by a second cross-sectional shape, where the first and second cross-sectional shapes are the same or different. In some embodiments, at least ten percent, at least twenty percent, at least thirty percent, at least forty percent, at least fifty percent, at least sixty percent, at least seventy percent, at least eighty percent, at least ninety percent or all of the length of the elongated photovoltaic module is characterized by the first cross-sectional shape. In some embodiments, the first cross-sectional shape is planar (e.g., has no arcuate side) and the second cross-sectional shape has at least one arcuate side. It will be appreciated that in these embodiments, the concentrator 54 will likewise have a varying shape. Alternatively, the concentrator 54 will not run the entire length of the elongated photovoltaic module.

In some embodiments, the substrate of the elongated photovoltaic module is made of a rigid plastic, metal, metal alloy, or glass. In some embodiments, the substrate of the elongated photovoltaic module is made of a urethane polymer, an acrylic polymer, a fluoropolymer, polybenzamidazole, polymide, polytetrafluoroethylene, polyetheretherketone, polyamide-imide, glass-based phenolic, polystyrene, cross-linked polystyrene, polyester, polycarbonate, polyethylene, polyethylene, acrylonitrile-butadiene-styrene, polytetrafluoro-ethylene, polymethacrylate, nylon 6,6, cellulose acetate butyrate, cellulose acetate, rigid vinyl, plasticized vinyl, or polypropylene. In some embodiments, the substrate 102 is made of aluminosilicate glass, borosilicate glass, dichroic glass, germanium/semiconductor glass, glass ceramic, silicate/fused silica glass, soda lime glass, quartz glass, chalcogenide/sulphide glass, fluoride glass, a glass-based phenolic, flint glass, or cereated glass.

In some embodiments, the substrate of the elongated photovoltaic module is made of a material such as polybenzamidazole (e.g., CELAZOLE®, available from Boedeker Plastics, Inc., Shiner, Tex.). In some embodiments, the substrate of the elongated photovoltaic module is made of polymide (e.g., DUPONT™ VESPEL®, or DUPONT™ KAPTON®, Wilmington, Del.). In some embodiments, the substrate of the elongated photovoltaic module is made of polytetrafluoroethylene (PTFE) or polyetheretherketone (PEEK), each of which is available from Boedeker Plastics, Inc. In some embodiments, the substrate of the elongated photovoltaic module is made of polyamide-imide (e.g., TORLON® PAI, Solvay Advanced Polymers, Alpharetta, Ga.).

In some embodiments, the substrate of the elongated photovoltaic module is made of a glass-based phenolic. Phenolic laminates are made by applying heat and pressure to layers of paper, canvas, linen or glass cloth impregnated with synthetic thermosetting resins. When heat and pressure are applied to the layers, a chemical reaction (polymerization) transforms the separate layers into a single laminated material with a “set” shape that cannot be softened again. Therefore, these materials are called “thermosets.” A variety of resin types and cloth materials can be used to manufacture thermoset laminates with a range of mechanical, thermal, and electrical properties. In some embodiments, the substrate of the elongated photovoltaic module is a phenoloic laminate having a NEMA grade of G-3, G-5, G-7, G-9, G-10 or G-11. Exemplary phenolic laminates are available from Boedeker Plastics, Inc.

In some embodiments, the substrate of the elongated photovoltaic module is made of polystyrene. Examples of polystyrene include general purpose polystyrene and high impact polystyrene as detailed in Marks' Standard Handbook for Mechanical Engineers, ninth edition, 1987, McGraw-Hill, Inc., p. 6-174, which is hereby incorporated by reference herein in its entirety. In still other embodiments, the substrate of the elongated photovoltaic module is made of cross-linked polystyrene. One example of cross-linked polystyrene is REXOLITE® (available from San Diego Plastics Inc., National City, Calif.). REXOLITE is a thermoset, in particular a rigid and translucent plastic produced by cross linking polystyrene with divinylbenzene.

In still other embodiments, the substrate of the elongated photovoltaic module is made of polycarbonate. Such polycarbonates can have varying amounts of glass fibers (e.g., 10%, 20%, 30%, or 40%) in order to adjust tensile strength, stiffness, compressive strength, as well as the thermal expansion coefficient of the material. Exemplary polycarbonates are ZELUX® M and ZELUX® W, which are available from Boedeker Plastics, Inc.

In some embodiments, the substrate of the elongated photovoltaic module is made of polyethylene. In some embodiments, the substrate of the elongated photovoltaic module is made of low density polyethylene (LDPE), high density polyethylene (HDPE), or ultra high molecular weight polyethylene (UHMW PE). Chemical properties of HDPE are described in Marks' Standard Handbook for Mechanical Engineers, ninth edition, 1987, McGraw-Hill, Inc., p. 6-173, which is hereby incorporated by reference herein in its entirety. In some embodiments, the substrate of the elongated photovoltaic module is made of acrylonitrile-butadiene-styrene, polytetrfluoro-ethylene (Teflon), polymethacrylate (lucite or plexiglass), nylon 6,6, cellulose acetate butyrate, cellulose acetate, rigid vinyl, plasticized vinyl, or polypropylene. Chemical properties of these materials are described in Marks' Standard Handbook for Mechanical Engineers, ninth edition, 1987, McGraw-Hill, Inc., pp. 6-172 through 6-175, which is hereby incorporated by reference in its entirety.

Additional exemplary materials that can be used to form the substrate of the elongated photovoltaic module are found in Modern Plastics Encyclopedia, McGraw-Hill; Reinhold Plastics Applications Series, Reinhold Roff, Fibres, Plastics and Rubbers, Butterworth; Lee and Neville, Epoxy Resins, McGraw-Hill; Bilmetyer, Textbook of Polymer Science, Interscience; Schmidt and Marlies, Principles of high polymer theory and practice, McGraw-Hill; Beadle (ed.), Plastics, Morgan-Grampiand, Ltd., 2 vols. 1970; Tobolsky and Mark (eds.), Polymer Science and Materials, Wiley, 1971; Glanville, The Plastics's Engineer's Data Book, Industrial Press, 1971; Mohr (editor and senior author), Oleesky, Shook, and Meyers, SPI Handbook of Technology and Engineering of Reinforced Plastics Composites, Van Nostrand Reinhold, 1973, each of which is hereby incorporated by reference herein in its entirety.

In some embodiments, a cross-section of the substrate of the elongated photovoltaic module is circumferential and has an outer diameter of between 3 mm and 100 mm, between 4 mm and 75 mm, between 5 mm and 50 mm, between 10 mm and 40 mm, or between 14 mm and 17 mm. In some embodiments, a cross-section of the substrate of the elongated photovoltaic module is circumferential and has an outer diameter of between 1 mm and 1000 mm.

In some embodiments, the substrate of the elongated photovoltaic module is a tube with a hollowed inner portion. In such embodiments, a cross-section of the substrate of the elongated photovoltaic module is characterized by an inner radius defining the hollowed interior and an outer radius. The difference between the inner radius and the outer radius is the thickness of the substrate 102. In some embodiments, the thickness of the substrate of the elongated photovoltaic module is between 0.1 mm and 20 mm, between 0.3 mm and 10 mm, between 0.5 mm and 5 mm, or between 1 mm and 2 mm. In some embodiments, the inner radius is between 1 mm and 100 mm, between 3 mm and 50 mm, or between 5 mm and 10 mm.

In some embodiments, the substrate of the elongated photovoltaic module has a length (perpendicular to the plane defined by FIG. 7) that is between 5 mm and 10,000 mm, between 50 mm and 5,000 mm, between 100 mm and 3000 mm, or between 500 mm and 1500 mm. In one embodiment, the substrate of the elongated photovoltaic module is a hollowed tube having an outer diameter of 15 mm and a thickness of 1.2 mm, and a length of 1040 mm. It will be appreciated that in many embodiments, the substrate of the elongated photovoltaic module will have a hollow core and will adopt a rigid tubular structure such as that formed by a glass tube.

In the apparatus for converting light energy into electric energy, the first wall is substantially the shape of an involute of the module oriented in a clockwise direction. The second wall is substantially the shape of an involute of the module oriented in a counterclockwise direction. The first and the second walls are limited to the height of the topmost portion of the elongated photovoltaic module in some embodiments. In some embodiments, the module is disposed upon or above a joining of the first wall and the second wall.

An apparatus for converting light energy into electric energy has a concentrator with at least two walls. An elongated photovoltaic module is disposed between the at least two walls and has a substrate, and a photovoltaic covering disposed on the substrate that is operable to convert light energy into electric energy. The two walls are limited to the height of the topmost portion of the elongated photovoltaic module. The at least two walls substantially have a shape of the involute of corresponding portions of the elongated photovoltaic module. In one case, the involute shape is over at least 90% of the area of the walls.

An apparatus for converting light energy into electric energy has a concentrator with at least two walls and an opening to a first direction that allows light energy into an interior portion of the apparatus. An elongated photovoltaic module is disposed between the at least two walls. The module has a substrate and a photovoltaic covering disposed on the substrate that is operable to convert light energy into electric energy. The at least two walls are limited to the height of the topmost portion of the elongated photovoltaic module and the at least two walls have substantially the shape of the involute of the surface of the elongated photovoltaic module. The ratio between the effective collection area of the apparatus and the effective collection area of the module is between pi/2 and pi.

An apparatus for converting light energy into electric energy has a concentrator with at least two walls. The concentrator has an opening to a first direction that allows light energy into an interior portion of the apparatus.

An elongated photovoltaic module is disposed between the at least two walls. The module has a substrate and a photovoltaic covering disposed on the substrate that is operable to convert light energy into electric energy. A cross-section of the module is circular in shape.

The at least two walls have substantially the shape of the involute of corresponding portions of the module and are limited to the height of the topmost portion of the elongated photovoltaic module.

An apparatus for converting light energy into electric energy has a concentrator with at least a first wall and a second wall of a reflective material and an opening defined by the first wall and the second wall. The opening is operable to admit light energy into an interior portion of the apparatus.

An elongated photovoltaic module is disposed between the first wall and the second wall and has a substrate and a photovoltaic covering disposed on the substrate. The module is operable to convert light energy into electric energy. The module has an omnifacial light gathering characteristic. The module is operable to generate electric energy from light energy striking the module in direct manner at a first area while contemporaneously being operable to generate electricity from light redirected from one of the walls to a second area of the area of the module.

The first wall has substantially the shape of an involute of the elongated photovoltaic module oriented in a clockwise direction. The second wall has substantially the shape of an involute of the elongated photovoltaic module oriented in a counterclockwise direction. The first and the second wall are limited to the height of the topmost portion of the elongated photovoltaic module. In one case, the module is disposed upon or above a joining of the first wall and the second wall.

In one case, the light directly striking the module is oriented in substantially in a perpendicular direction to the first area. In one case, the light indirectly striking the module is oriented in a substantially perpendicular direction to the second area.

The concentrator can be formed at least in part from a specular material. The concentrator can be formed at least in part from a diffuse material. The concentrator can be formed as a sheet of material no thicker than ½ inch. The concentrator can be formed having a thickness greater than ½ inch. The concentrator can be formed with a reflecting material disposed upon a substrate. The concentrator can be made of a polished reflecting material and a sealant material disposed upon the reflecting material.

The module can be characterized by a first side disposed towards the first wall, along with a longitudinal axis defining a first portion of the module disposed in a first direction towards the opening and a second portion of the module disposed in a direction substantially anti-parallel to the first direction. The light that directly strikes the module can strike the first portion of the module. The light that is redirected to the module can strike the first side. The light that is redirected to the module can strike the second portion.

Another apparatus for converting light energy into electric energy can be envisioned. The apparatus has a concentrator having at least two walls, and having an opening to a first direction that allows light energy into an interior portion of the apparatus.

Thus, a photovoltaic apparatus having an elongated photovoltaic device substantially using an involute reflector is described and illustrated. Those skilled in the art will recognize that many modifications and variations of the present invention are possible without departing from the invention. Of course, the various features depicted in each of the figures and the accompanying text may be combined together.

Accordingly, it should be clearly understood that the present invention is not intended to be limited by the particular features specifically described and illustrated in the drawings, but the concept of the present invention is to be measured by the scope of the appended claims. It should be understood that various changes, substitutions, and alterations could be made hereto without departing from the spirit and scope of the invention as described by the appended claims that follow.

What is claimed is:

1. An apparatus for converting light energy into electric energy, the apparatus comprising:
a concentrator, comprising at least a first wall and a second wall, wherein the first wall and the second wall comprise a material that reflects light energy, the concentrator having an opening defined by the first wall and the second wall, the opening operable to admit light energy into an interior portion of the apparatus;
an elongated photovoltaic module disposed in the interior portion of the apparatus between the two walls, the elongated photovoltaic module comprising:
(i) a substrate;
(ii) a photovoltaic covering disposed on the substrate and operable to convert light energy into electric energy; wherein
the elongated photovoltaic module operable to generate electric energy from light energy directly striking the elongated photovoltaic module without contacting the concentrator as well as light energy redirected from the concentrator to the elongated photovoltaic module;
at least a portion of the first wall having substantially the shape of an involute of a surface of the elongated photovoltaic module oriented in a clockwise direction with respect to a cross-section of the elongated photovoltaic module; and
at least a portion of the second wall having substantially the shape of an involute of a surface of the elongated photovoltaic module oriented in a counter-clockwise direction with respect to the cross-section of the elongated photovoltaic module.

2. The apparatus of claim 1 wherein the first wall and the second wall are joined together by a joining piece and wherein the elongated photovoltaic module is disposed upon or above the joining piece.

3. The apparatus of claim 1 wherein the first wall and the second wall do not touch each other.

4. The apparatus of claim 1 wherein the concentrator is formed at least in part from a specular material.

5. The apparatus of claim 1 wherein the concentrator is formed at least in part from a diffuse material.

6. The apparatus of claim 1 wherein the concentrator is formed as a sheet of material no thicker than ½ inch.

7. The apparatus of claim 1 wherein the concentrator is formed having a thickness greater than ½ inch.

8. The apparatus of claim 1 wherein the concentrator is formed with a reflecting material disposed upon a substrate.

9. The apparatus of claim 1 wherein the concentrator comprises a polished reflecting material and a sealant material disposed upon the reflecting material.

10. The apparatus of claim 1 wherein the elongated photovoltaic module is characterized by:
a first side disposed towards the first wall;
a longitudinal axis defining:
a first portion of the module disposed in a first direction towards the opening;
a second portion of the module disposed in a direction substantially opposite to the first direction; and
the light that directly strikes the module strikes the first portion of the module.

11. The apparatus of claim 10 wherein the light that is redirected to the module strikes the first side.

12. The apparatus of claim 10 wherein the light that is redirected to the module strikes the second portion.

13. The apparatus of claim 1, wherein the first wall and the second wall are each limited to a height of a topmost portion of the elongated photovoltaic module

14. An apparatus for converting light energy into electric energy, the apparatus comprising:
a concentrator, comprising at least two walls, the concentrator having an opening to a first direction that allows light energy into an interior portion of the apparatus;
an elongated photovoltaic module disposed between the at least two walls in the interior portion of the apparatus, the elongated photovoltaic module comprising:
a substrate;
a photovoltaic covering disposed on the substrate and operable to convert light energy into electric energy; and
at least a portion of each of the at least two walls each having a shape of an involute of corresponding portions of the surface of elongated photovoltaic module.

15. The apparatus of claim 14, wherein the at least two walls are each limited to a height of a topmost portion of the elongated photovoltaic module.

16. An apparatus for converting light energy into electric energy, the apparatus comprising:
a concentrator, comprising at least two walls;
an elongated photovoltaic module disposed between the at least two walls, having:
a substrate;
a photovoltaic covering disposed on the substrate and operable to convert light energy into electric energy;
at least a portion of each of the at least two walls each having a shape of an involute of corresponding portions of a surface of elongated photovoltaic module over at least 90% of the area of the corresponding portions of the elongated photovoltaic module; and
the at least two walls limited to the height of the topmost portion of the elongated photovoltaic module.

17. An apparatus for converting light energy into electric energy, the apparatus comprising:
a concentrator, comprising at least two walls, the concentrator having an opening to a first direction that allows light energy into an interior portion of the apparatus;
an elongated photovoltaic module disposed between the at least two walls, having:
a substrate;
a photovoltaic covering disposed on the substrate and operable to convert light energy into electric energy;
the at least two walls limited to the height of the topmost portion of the elongated photovoltaic module;
at least a portion of each of the at least two walls each having substantially the shape of an involute of the elongated photovoltaic module; and
the ratio between the effective collection area of the apparatus and the effective collection area of the elongated photovoltaic module is between pi/2 and pi.

18. An apparatus for converting light energy into electric energy, the apparatus comprising:
a concentrator, comprising at least two walls, the concentrator having an opening to a first direction that allows light energy into an interior portion of the apparatus;
an elongated photovoltaic module disposed in the interior potion of the apparatus between the at least two walls, having:
a substrate;
a photovoltaic covering disposed on the substrate and operable to convert light energy into electric energy;
a cross-section of the elongated photovoltaic module being circular in shape;
at least a portion of each of the at least two walls each having a shape of an involute of corresponding portions of a surface of elongated photovoltaic module; and
the at least two walls limited to the height of the topmost portion of the elongated photovoltaic module.

19. An apparatus for converting light energy into electric energy, the apparatus comprising:
a concentrator, comprising at least a first wall and a second wall of a reflective material, the concentrator having an opening defined by the first wall and the second wall, operable to admit light energy into an interior portion of the apparatus;
an elongated photovoltaic module disposed in the interior portion of the apparatus between the two walls, having:
a substrate;
a photovoltaic covering disposed on the substrate and operable to convert light energy into electric energy;
the elongated photovoltaic module having an omnifacial light gathering characteristic; the module operable to generate electric energy from light energy striking the module in direct manner, without first striking the concentrator, at a first area while contemporaneously operable to generate electricity from light redirected from one of the first wall and the second wall to a second area;
the light directly striking the module oriented in substantially a perpendicular direction to the first area;
at least a portion of the first wall having substantially the shape of an involute of a surface of the elongated photovoltaic module oriented in a clockwise direction with respect to a cross-section of the elongated photovoltaic module;
at least a portion of the second wall having substantially the shape of an involute of the elongated photovoltaic module oriented in a counterclockwise direction with respect to the cross-section of the elongated photovoltaic module; and
the first and the second wall limited to the height of the topmost portion of the elongated photovoltaic module.

20. The apparatus of claim 19 wherein the elongated photovoltaic module is disposed upon or above a joining of the first wall and the second wall.

21. An apparatus for converting light energy into electric energy, the apparatus comprising:
a concentrator, comprising at least a first wall and a second wall of a reflective material, the concentrator having an opening defined by the first wall and the second wall, operable to admit light energy into an interior portion of the apparatus;
an elongated photovoltaic module disposed in the interior portion of the apparatus between first wall and the second wall, having:
a substrate;
a photovoltaic covering disposed on the substrate and operable to convert light energy into electric energy;
the elongated photovoltaic module having an omnifacial light gathering characteristic; the module operable to generate electric energy from light energy striking the module in a direct manner at a first area while contemporaneously operable to generate electricity from light redirected from one of the first wall and the second wall to a second area;
the light directly striking the module oriented in substantially a perpendicular direction to the second area;
at least a portion of the the first wall having substantially the shape of an involute of the elongated photovoltaic module oriented in a clockwise direction with respect to a cross-section of the elongated photovoltaic module;
the second wall having substantially the shape of an involute of the elongated photovoltaic module oriented in a counterclockwise direction with respect to the cross-section of the elongated photovoltaic module; and
the first and the second wall limited to the height of the topmost portion of the elongated photovoltaic module.

22. The apparatus of claim 21 wherein the elongated photovoltaic module is disposed upon or above a joining of the first wall and the second wall.

23. An apparatus for converting light energy into electric energy, the apparatus comprising:
a concentrator, comprising at least a first wall and a second wall of a reflecting material, the concentrator having an opening defined by the first wall and the second wall, operable to admit light energy into an interior portion of the apparatus;
an elongated photovoltaic module, the module characterized by a longitudinal axis that delineates a first portion and a second portion of the module, the module disposed between the two walls and having:
a substrate;
a photovoltaic covering disposed on the substrate and operable to convert light energy into electric energy;
the first portion disposed in a first direction;
the second portion disposed in a second direction;
the elongated photovoltaic module operable to generate electric energy from light energy directly striking the module without striking the concentrator as well as from light energy redirected from the concentrator to module;
at least a portion of the first wall having substantially the shape of an involute of the elongated photovoltaic module oriented in a clockwise direction with respect to a cross-section of the elongated photovoltaic module;
at least a portion of the second wall having substantially the shape of an involute of the elongated photovoltaic module oriented in a counterclockwise direction with respect to a cross-section of the elongated photovoltaic module; and
the first wall and the second wall limited to the height of the topmost portion of the elongated photovoltaic module.

24. The apparatus of claim 23 wherein the elongated photovoltaic module is disposed upon or above a joining of the first wall and the second wall.

25. The apparatus of claim 1, wherein said substrate has a Young's modulus of 20 GPa or greater.

26. The apparatus of claim 1, wherein said substrate has a Young's modulus of 40 GPa or greater.

27. The apparatus of claim 1, wherein said substrate has a Young's modulus of 70 GPa or greater.

28. The apparatus of claim 1, wherein said substrate is made of a linear material.

29. The apparatus of claim 1, wherein all or a portion of the substrate is a rigid tube or a rigid solid rod.

30. The apparatus of claim 1, wherein all or a portion of the substrate is characterized by a circular cross-section, an ovoid cross-section, a triangular cross-section, a pentangular cross-section, a hexagonal cross-section, a cross-section having at least one arcuate portion, or a cross-section having at least one curved portion.

31. The apparatus of claim 1, wherein a first portion of the substrate is characterized by a first cross-sectional shape and a second portion of the substrate is characterized by a second cross-sectional shape.

32. The apparatus of claim 31, wherein the first cross-sectional shape and the second cross-sectional shape are the same.

33. The apparatus of claim 31, wherein the first cross-sectional shape and the second cross-sectional shape are different.

34. The apparatus of claim 31, wherein at least ninety percent of the length of the substrate is characterized by the first cross-sectional shape.

35. The apparatus of claim 31, wherein the first cross-sectional shape is planar and the second cross-sectional shape has at least one arcuate side.
